(19) United States
(12) Patent Application Publication
(10) Pub. No.: US 2024/0158290 A1
(43) Pub. Date: May 16, 2024

(54) DUAL TEXTURED GLASS ARTICLES AND METHODS OF MAKING THE SAME

(71) Applicant: CORNING INCORPORATED, CORNING, NY (US)

(72) Inventors: Ronghua Chen, Fuzhou City (CN); Matthew Wade Fenton, Elmira, NY (US); Yuhui Jin, Painted Post, NY (US); Kevin Ray Maslin, Athens, PA (US); Meng Shang, Painted Post, NY (US)

(21) Appl. No.: 18/510,018

(22) Filed: Nov. 15, 2023

(30) Foreign Application Priority Data
Nov. 16, 2022 (CN) 202211433963.1

(51) Int. Cl. C03C 15/00; H05K 5/03

(52) U.S. Cl. CPC C03C 15/00; H05K 5/03

(57) ABSTRACT

Disclosed herein are dual-textured glass articles. The glass articles may include a glass substrate comprising a first major surface and a second major surface. The first major surface may be opposite the second major surface. At least a portion of the first major surface comprises a dual-texture. The dual-texture may comprise a plurality of first features and a plurality of second features. The plurality of first features comprise protrusions from the first major surface and the plurality of second features comprise indentations in the first major surface and indentations in the plurality of first features.

This application claims the benefit of priority of Chinese Application Serial No. 202211433963.1 filed on Nov. 16, 2022, the content of which is relied upon and incorporated herein by reference in its entirety.

### BACKGROUND

### Field

The present specification generally relates to textured glass articles and, more specifically, to textured glass articles that are useful in display applications.

### Technical Background

Electronic devices, such as, smartphones, tablets, utilize glass-based materials. For example, screens on such portable electronic devices may be made of glass-based materials. Textured surfaces to provide a paper-like tactile experience when using a stylus may be included on the glass-based materials. However, current methods for forming a paper-like texture on glass-based materials generally use a coating or laminate on the surface of the glass, which compromises the feel of the glass when touched by fingers.

Accordingly, a need exists for glass-based materials with a textured surface that provides a paper-like tactile experience when using a stylus without compromised finger touch experience. Additionally, there is a need for methods of producing such materials. This need and other needs are addressed by the present disclosure.

### SUMMARY

According to one or more embodiments, dual-textured glass articles may comprise a glass substrate comprising a first major surface and a second major surface, the first major surface opposite the second major surface, wherein at least a portion of the first major surface comprises a dual-texture, the dual-texture comprising a plurality of first features and a plurality of second features, wherein the plurality of first features comprise protrusions from the first major surface and the plurality of second features comprise indentations in the first major surface and indentations in the plurality of first features.

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments and are incorporated into and constitute a part of this specification. The drawings illustrate the various embodiments described herein and, together with the description, serve to explain the principles and operations of the claimed subject matter.

### BRIEF DESCRIPTION OF THE DRAWINGS

FIG. 1A schematically depicts a cross-sectional view of a dual-textured glass article, according to one or more embodiments described herein;

FIG. 1B schematically depicts a top view of a dual-textured glass article, according to one or more embodiments described herein;

FIG. 2A schematically depicts a top view of a consumer electronic device, according to one or more embodiments described herein;

FIG. 2B schematically depicts an orthogonal view of a consumer electronic device, according to one or more embodiments described herein;

FIG. 3A schematically depicts a cross-sectional view of a glass article, according to one or more embodiments described herein;

FIG. 3B schematically depicts a cross-sectional view of a textured glass article, according to one or more embodiments described herein;

FIG. 3C schematically depicts a cross-sectional view of a textured glass article, according to one or more embodiments described herein;

FIG. 4 depicts a profile of a surface of a dual-textured glass article according to an embodiment of Example 2;

FIG. 5 depicts a profile of a surface of a dual-textured glass article according to an embodiment of Example 2; and

FIG. 6 depicts a profile of a surface of a dual-textured glass article according to an embodiment of Example 2.

### DETAILED DESCRIPTION

Reference will now be made in detail to dual-textured glass articles and methods for making dual-textured glass articles. In particular, the dual-textured glass articles are suitable for use as display covers in electronic devices. The dual-textured glass articles may provide a paper-like tactile experience when a user interacts with the dual-textured glass article using a stylus. Additionally, the dual-textured glass articles may have a desirable tactile experience when a user interacts with the dual-textured glass articles with fingers. Furthermore, the dual-textured glass articles may have favorable optical properties when employed in electronic displays. This combination of features may make the dual-textured glass articles described herein desirable for use in electronic devices, such as tablets, where a user may interact with the display of the electronic device using a stylus, fingers, or both.

In the following description, like reference characters designate like or corresponding parts throughout the several views shown in the figures. It is also understood that, unless otherwise specified, terms such as “top,” “bottom,” “outward,” “inward,” and the like are words of convenience and are not to be construed as limiting terms. Whenever a group is described as consisting of at least one of a group of elements or combinations thereof, it is understood that the group may consist of any number of those elements recited, either individually or in combination with each other. Unless otherwise specified, a range of values, when recited, includes both the upper and lower limits of the range as well as any ranges therebetween. As used herein, the indefinite articles “a,” “an,” and the corresponding definite article “the” mean “at least one” or “one or more,” unless otherwise specified. It also is understood that the various features disclosed in the specification and the drawings can be used in any and all combinations.

Unless otherwise specified, all compositions of the glasses described herein are expressed in terms of mole percent (mol %), and the constituents are provided on an oxide basis. Unless otherwise specified, all temperatures are expressed in terms of degrees Celsius (° C.). All ranges disclosed in this specification include any and all ranges and subranges encompassed by the broadly disclosed ranges whether or not explicitly stated before or after a range is disclosed

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. As utilized herein, when the term “about” is used to modify a value, the exact value is also disclosed.

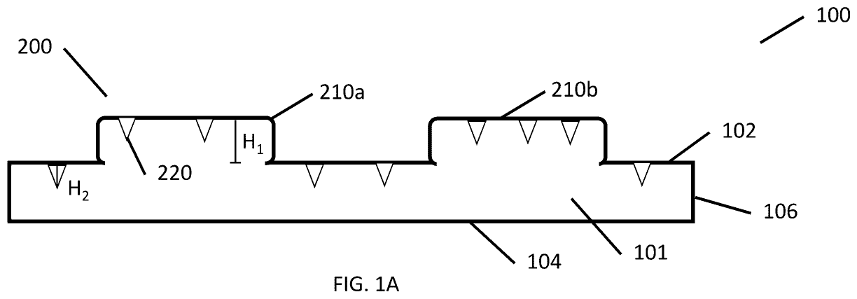

Referring now to FIGS. 1A and 1B, according to one or more embodiments described herein, a dual-textured glass article 100 may comprise a glass substrate 101, a first major surface 102, and a second major surface 104. The dual-textured glass article 100 may further comprise edges 106. In embodiments where the dual-textured glass article 100 is a sheet, as schematically depicted in FIGS. 1A and 1B, the first major surface 102 may be opposite the second major surface 104. In embodiments, the first major surface 102 and the second major surface 104 may be substantially planar. A thickness of the dual-textured glass article 100 may be measured between the first major surface 102 and the second major surface 104. In embodiments, at least a portion of the first major surface 102 or the second major surface 104 comprises a dual-texture. In embodiments, at least a portion of the first major surface 102 comprises a dual-texture, while the second major surface 104 may be substantially free from the dual-texture. In embodiments, substantially all of the first major surface 102 may comprise the dual-texture.

The dual-texture described herein may be imparted onto glass articles having any suitable composition. For example, without limitation, the dual-texture described herein may be imparted onto a glass article having any composition that is suitable for use in an electronic display. In embodiments, the dual-textured glass article 100 may comprise from 55 mol. % to 70 mol. % SiO₂, from 10 mol. % to 20 mol. % Al₂O₃, from 0 mol. % to 5 mol. % P₂O₅, from 0 mol. % to 5 mol. % B₂O₃, from 0 mol. % to 5 mol. % MgO, from 0 mol. % to 2.5 mol. % ZnO, from 0 mol. % to 10 mol. % Li₂O, from 5 mol. % to 15 mol. % Na₂O, from 0 mol. % to 1 mol. % K₂O, and from 0 mol. % to 1 mol. % TiO₂.

Referring still to FIGS. 1A and 1B, the structure of the dual-texture 200 is depicted. The dual-texture 200 on a first major surface 102 of the dual-textured glass article 100 may include a plurality of first features 210 and a plurality of second features 220. In embodiments, the plurality of first features 210 comprises protrusions extending from the first major surface 102. In embodiments, the plurality of second features 220 comprises indentations in the first major surface 102 and indentations in the plurality of first features 210.

In embodiments, the plurality of first features 210 may be randomly arranged on the first major surface 102 of the dual-textured glass article 100. As described herein, a “random arrangement” refers to an arrangement with no discernable, repeated pattern over the first major surface 102 of the dual-textured glass article 100. Without intending to be bound by theory, the use of a random arrangement of the first features 210 may improve the optical properties of the dual-textured glass article. For example, when the dual-textured glass article 100 is used as part of a display, a random arrangement of first features 210 in the dual-texture 200 may reduce sparkle of the display. Additionally, the use of a random arrangement of first features 210 in the dual-texture 200 may reduce or eliminate perceived waviness that may result from periodic textures or textures with repeated patterns.

In embodiments, the plurality of first features 210 may have a cross-sectional shape in a plane parallel to the first major surface 102. In embodiments, each first feature 210 may have a substantially circular, elliptical, oval, or polygonal shape. It should be noted that, in embodiments, first features 210 may not be perfectly circular, elliptical, oval or polygonal due to limitations in the methods for producing the first features 210 on the first major surface 102. However, the cross-sectional shape of a first feature 210 may be approximated by such shapes. Accordingly, the first features 210 may have a cross-sectional shape that is substantially circular, elliptical, oval, or polygonal. In the embodiment depicted in FIG. 1B, the first features 210 have substantially circular cross-sectional shapes. However, it should be understood that other cross-sectional shapes are contemplated and possible.

In embodiments, the first features 210 may have sizes from 50 μm to 1000 μm. For example, without limitation, the first features 210 may have sizes from 50 μm to 1000 μm, from 150 μm to 1000 μm, from 250 μm to 1000 μm, from 350 μm to 1000 μm, from 450 μm to 1000 μm, from 550 μm to 1000 μm, from 650 μm to 1000 μm, from 750 μm to 1000 μm, from 850 μm to 1000 μm, from 950 μm to 1000 μm, from 50 μm to 950 μm, from 50 μm to 850 μm, from 50 μm to 750 μm, from 50 μm to 650 μm, from 50 μm to 550 μm, from 50 μm to 450 μm, from 50 μm to 350 μm, from 50 μm to 250 μm, from 50 μm to 150 μm, or any sub-range formed from these endpoints. As described herein, the size of a first feature 210 may refer to the diameter of the smallest circle enclosing the first feature 210 at the first major surface 102. For example, in FIG. 1B, the size of the first feature 210d may be diameter D₁ of first feature 210d at first major surface 102.

In embodiments, the first features 210 may have heights of from 0.1 μm to 10 μm. For example, without limitation, the first features 210 may have heights of from 0.1 μm to 10 μm, from 0.5 μm to 10 μm, from 1 μm to 10 μm, from 2 μm to 10 μm, from 3 μm to 10 μm, from 4 μm to 10 μm, from 5 μm to 10 μm, from 6 μm to 10 μm, from 7 μm to 10 μm, from 8 μm to 10 μm, from 9 μm to 10 μm, from 0.1 μm to 9 μm, from 0.1 μm to 8 μm, from 0.1 μm to 7 μm, from 0.1 μm to 6 μm, from 0.1 μm to 5 μm, from 0.1 μm to 4 μm, from 0.1 μm to 3 μm, from 0.1 μm to 2 μm, from 0.1 μm to 1 μm, from 0.1 μm to 0.5 μm, or any sub-range formed from these endpoints. As described herein, the height of a first feature 210 may refer to a maximum distance that the first feature 210 protrudes from a major surface of the dual-textured glass article in a direction normal to the major surface. For example, in FIG. 1A, the height H₁ of the first feature 210a is the maximum distance that the first feature 210a protrudes from the first major surface 102 in a direction normal to the first major surface 102.

In embodiments, a distance between first features 210 may be from 50 μm to 1500 μm. As described herein, the distance between the first features 210 is measured from the center to center of adjacent first features. For example, without limitation, a distance between first feature 210 may be from 50 μm to 1500 μm, from 200 μm to 1500 μm, from 350 μm to 1500 μm, from 500 μm to 1500 μm, from 650 μm to 1500 μm, from 800 μm to 1500 μm, from 950 μm to 1500 μm, from 1100 μm to 1500 μm, from 1250 μm to 1500 μm, from 1400 μm to 1500 μm, from 50 μm to 1400 μm, from 50 μm to 1250 μm, from 50 μm to 1100 μm, from 50 μm to 950 μm, from 50 μm to 800 μm, from 50 μm to 650 μm, from 50 μm to 500 μm, from 50 μm to 350 μm, from 50 μm to 200 μm, or any sub-range formed from these endpoints. Without intending to be bound by theory, the distance between the first features 210 may be large enough that the tip of a stylus may enter depressions between the first features 210 as the stylus is moved across the first major surface 102 of the dual-textured glass article 100. It is contemplated that the first features 210 may provide resistance to the movement of the stylus across the dual-textured surface when the tip of the stylus is able to enter the space between the first features 210. This resistance may give the use a tactile experience similar to using a pen or pencil on paper when using a stylus on the dual-textured surface of the glass article. For example, in FIG. 1B, the distance between first feature 210b and first feature 210c may be distance D₂, measured at first major surface 102.

In embodiments, the second features 220 may have sizes from 0.5 μm to 20 μm. For example, without limitation, the second features 220 may have sizes from 0.5 μm to 20 μm, from 1 μm to 20 μm, from 3 μm to 20 μm, from 5 μm to 20 μm, from 7 μm to 20 μm, from 9 μm to 20 μm, from 11 μm to 20 μm, from 13 μm to 20 μm, from 15 μm to 20 μm, from 17 μm to 20 μm, from 19 μm to 20 μm, from 0.5 μm to 19 μm, from 0.5 μm to 17 μm, from 0.5 μm to 15 μm, from 0.5 μm to 13 μm, from 0.5 μm to 11 μm, from 0.5 μm to 9 μm, from 0.5 μm to 7 μm, from 0.5 μm to 5 μm, from 0.5 μm to 3 μm, from 0.5 μm to 1 μm, or any sub-range formed from these endpoints. As described herein the size of a second feature 220 refers to the diameter of the smallest circle enclosing the second feature 220 at first major surface 102. For example, in FIG. 1B, the size of the second feature 220a may be diameter D₃ of second feature 220a at the first major surface 102.

In embodiments, the second features 220 may depths from 0.1 μm to 1.5 μm. For example, without limitation, the second features 220 may have depths from 0.1 μm to 1.5 μm, from 0.3 μm to 1.5 μm, from 0.5 μm to 1.5 μm, from 0.7 μm to 1.5 μm, from 0.9 μm to 1.5 μm, from 1.1 μm to 1.5 μm, from 1.3 μm to 1.5 μm, from 0.1 μm to 1.3 μm, from 0.1 μm to 1.1 μm, from 0.1 μm to 0.9 μm, from 0.1 μm to 0.7 μm, from 0.1 μm to 0.5 μm, from 0.1 μm to 0.3 μm, or any sub-range formed from these endpoints. As described herein, the depth of a second feature 220 refers to a maximum distance that the second feature 220 is indented into either a major surface of the dual-textured glass article or a first feature on the major surface of the dual textured glass article in a direction normal to the major surface. For example, in FIG. 1A, the depth H₂ of a second feature 220 is the maximum distance the second feature 220 is indented into the first major surface 102 or a first feature 210 in a direction normal to the first major surface 102.

Without intending to be bound by theory, the second features 220 may improve the optical qualities of the dual-textured glass article. For example, the second features 220 may contribute to the surface roughness, haze, sparkle, and diffusion characteristics of the dual-textured glass article. Additionally, the second features 220 may contribute to a satisfying finger touch experience when a user interacts with the dual-textured surface of the glass article.

In embodiments, the portion of the first major surface 102 comprising the dual-texture 200 may have a haze of from 1% to 40%. For example, without limitation, the portion of the first major surface 102 comprising the dual-texture 200 may have a haze of from 1% to 40%, from 5% to 40%, from 10% to 40%, from 15% to 40%, from 20% to 40%, from 25% to 40%, from 30% to 40%, from 35% to 40%, from 1% to 35%, from 1% to 30%, from 1% to 25%, from 1% to 20%, from 1% to 15%, from 1% to 10%, from 1% to 5%, or any sub-range formed from these endpoints. As described herein, haze refers to “transmittance haze,” and is measured using a Haze-gard Transparency Transmission Haze Meter, according to ASTM D1003 “Standard Test Method for Haze and Luminous Transmittance of Transparent Plastics” using Illuminant C. Without intending to be bound by theory, when haze is relatively low the dual-textured glass based article may have improved performance in high ambient light conditions, such as bright sunlight, when used as a cover for an electronic display.

In embodiments, the portion of the first major surface 102 comprising the dual-texture 200 may have a surface roughness from 0.1 μm to 1.5 μm. For example, without limitation, the portion of the first major surface 102 comprising the dual-texture 200 may have a surface roughness from 0.1 μm to 1.5 μm, from 0.3 μm to 1.5 μm, from 0.5 μm to 1.5 μm, from 0.7 μm to 1.5 μm, from 0.9 μm to 1.5 μm, from 1.1 μm to 1.5 μm, from 1.3 μm to 1.5 μm, from 0.1 μm to 1.3 μm, from 0.1 μm to 1.1 μm, from 0.1 μm to 0.9 μm, from 0.1 μm to 0.7 μm, from 0.1 μm to 0.5 μm, from 0.1 μm to 0.3 μm, or any sub-range formed from these endpoints. As described herein, unless otherwise specified, “surface roughness” refers to Rₐ, the arithmetical mean deviation of a measured profile. Unless otherwise specified, Rₐ is measured on a Zygo 9000 with the following settings: Scan size was 220 microns by 220 microns; Objective: 20×; Image Zoom 2×; Camera resolution 0.224 microns; Filter: Form Removed: Cylinder. Without intending to be bound by theory, the surface roughness of the dual-textured glass article may contribute to a pleasing tactile experience when a user touches the dual-textured glass article 100 with a finger.

The portion of the first major surface 102 comprising the dual-texture 200 may be characterized by sparkle. “Sparkle,” “sparkle contrast,” “display sparkle,” “pixel power deviation,” “PPD”, or like terms refers to the visual phenomenon that occurs when a textured transparent surface is combined with a pixelated display. Generally speaking, quantitative assessment of sparkle involves imaging a lit display or simulated display with the textured surface in the field of view. The calculation of sparkle for an area P is equal to σ(P)/μ(P), where σ(P) is the standard deviation of the distribution of integrated intensity for each display pixel contained within area P divided by the mean intensity μ(P). Following the guidance in: (1) J. Gollier, et al., “Apparatus and method for determining sparkle,” U.S. Pat. No. 9,411,180B2, United States Patent and Trademark Office, 20 Jul. 2016; (2) A. Stillwell, et al., “Perception of Sparkle in Anti-Glare Display Screens,” JSID 22(2), 129-136 (2014); and (3) C. Cecala, et al., “Fourier Optics Modeling of Display Sparkle from Anti-Glare Cover Glass: Comparison to Experimental Data”, Optical Society of America Imaging and Applied Optics Congress, JW5B.8 (2020); one skilled in the art can build an imaging system to quantify sparkle. Alternatively, a commercially available system (e.g. the SMS-1000, Display Messtechnik & Systeme GmbH & Co. KG, Germany) can also be used. As described herein, sparkle is measured with a 140 PPI display. A 140 PPI display (e.g. Z50, Lenovo Group Limited, Hong Kong) with only the green subpixels lit (R=0, B=0, G=255), at full display brightness is imaged using a f=50 mm lens/machine vision camera combination (e.g. C220503 1:2.8 50 mm Φ30.5, Tamron, Japan) and Stingray F-125 B, Allied Vision Technologies GmbH, Germany). The lens settings are aperture=5.6, depth of field=0.3, working distance=about 290 mm; with these settings, the ratio of display pixels to camera pixels is approximately 1 to 9. The field of view for analysis contains approximately 7500 display pixels. Camera settings have the gain and gamma correction turned off. Periodic intensity variations from, e.g. the display, and non-periodic intensity variations, e.g. dead pixels, are removed during analysis prior to the calculation of sparkle.

In embodiments, the portion of the first major surface 102 comprising the dual-texture 200 may have a sparkle of less than or equal to 7%. For example, without limitation, the portion of the first major surface 102 comprising the dual-texture 200 may have a sparkle of less than or equal to 7%, less than or equal to 6%, less than or equal to 5%, less than or equal to 4%, less than or equal to 3%, or even less than or equal to 2%.

In embodiments, the portion of the first major surface 102 comprising the dual-texture 200 may have a diffusion of greater than or equal to 20%. For example, without limitation, the portion of the first major surface 102 comprising the dual-texture 200 may have a diffusion of greater than or equal to 20%, greater than or equal to 30%, greater than or equal to 40%, greater than or equal to 50%, or even greater than or equal to 70%. Without intending to be bound by theory, when the diffusion is greater than 20% the glass article may have favorable anti-glare properties. As described herein, diffusion may be measured using a commercially available system, SMS-1000, Display Messtechnik & Systeme GmbH & Co. KG, Germany.

The portion of the first major surface 102 comprising the dual-texture 200 may be characterized by distinctness of image. “Distinctness-of-reflected image,” “distinctness-of-image,” “DOI” or like term is defined by method A of ASTM procedure D5767 (ASTM 5767), entitled “Standard Test Methods for Instrumental Measurements of Distinctness-of-Image Gloss of Coating Surfaces.” In accordance with method A of ASTM 5767, glass reflectance factor measurements are made on the at least one roughened surface of the glass article at the specular viewing angle and at an angle slightly off the specular viewing angle. The values obtained from these measurements are combined to provide a DOI value. In particular, DOI is calculated according to equation (1):

DOI=[1−Rₒₛ/Rₛ]×100 (1)

where Rₛ is the relative amplitude of reflectance in the specular direction and Rₒₛ is the relative amplitude of reflectance in an off-specular direction. As described herein, Rₒₛ, unless otherwise specified, is calculated by averaging the reflectance over an angular range from 0.2° to 0.4° away from the specular direction. Rₛ can be calculated by averaging the reflectance over an angular range of ±0.05° centered on the specular direction. Both Rₛ and Rₒₛ can be measured using a goniophotometer (Rhopoint IQ (Goniophotometer) 20°/60°/85°, Rhopoint Instruments) that is calibrated to a certified black glass standard, as specified in ASTM procedures D523 and D5767. The Rhopoint IQ instrument uses a detector array in which the specular angle is centered about the highest value in the detector array. DOI is evaluated using the 2-side (reflections allowed from both glass surfaces, nothing coupled to glass) method, where the result is referred to as the “uncoupled distinctness-of-image.” The 2-side measurement enables gloss, reflectance, and DOI to be determined for the glass article as a whole. The Rₒₛ/Rₛ ratio can be calculated from the average values obtained for Rₛ and Rₒₛ as described above. “20° DOI,” or “DOI 20°” refers to DOI measurements in which the light is incident on the sample at 20° off the normal to the glass surface, as described in ASTM D5767. The measurement of either DOI or common gloss using the 2-side method can best be performed in a dark room or enclosure so that the measured value of these properties is zero when the sample is absent.

In embodiments, the portion of the first major surface 102 comprising the dual-texture 200 may have a DOI from 20% to 92%. For example, without limitation, the portion of the first major surface 102 comprising the dual-texture 200 may have a DOI from 20% to 92%, from 30% to 92%, from 40% to 92%, from 50% to 92%, from 60% to 92%, from 70% to 92%, from 80% to 92%, from 90% to 92%, from 20% to 90%, from 20% to 80%, from 20% to 70%, from 20% to 60%, from 20% to 50%, from 20% to 40%, from 20% to 30%, or any sub-range formed from these endpoints.

In embodiments, the portion of the first major surface 102 comprising the dual-texture 200 may have a Gloss 60° value from 20% to 100%. For example, without limitation, the first major surface 102 comprising the dual-texture 200 may have a Gloss 60° value from 20% to 100%, from 30% to 100%, from 40% to 100%, from 50% to 100%, from 60% to 100%, from 70% to 100%, from 80% to 100%, from 90% to 100%, from 20% to 90%, from 20% to 80%, from 20% to 70%, from 20% to 60%, from 20% to 50%, from 20% to 40%, from 20% to 30%, or any sub-range formed from these endpoints. As described herein, a Gloss 60° value refers to a measurement taken at 60° from vertical using a commercially available Rhopoint Gloss Meter.

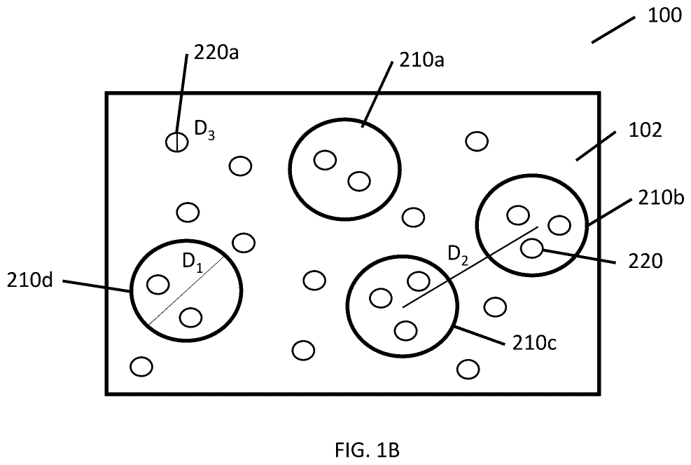

The dual-textured glass articles 100 described herein may be incorporated into another article, such as but not limited to, an article with a display. Articles comprising a display may include consumer electronics such as mobile phones, tablets, and computers. An exemplary article incorporating a dual-textured glass article 100 is shown in FIGS. 2A and 2B. Specifically, FIGS. 2A and 2B show a consumer electronic device 300 including a housing 302 having a front 304, back 306, and side surfaces 308; electrical components (not shown) that are at least partially inside or entirely within the housing and including at least a controller, a memory, and a display 310 at or adjacent to the front 304 of the housing 302; and cover substrate 312 at or over the front 304 of the housing 303 such that it is over the display 310. In embodiments, at least a portion of the cover substrate 312 may comprise any of the dual-textured glass articles described herein. In embodiments, the entirety of the cover substrate 312 comprises any of the dual-textured glass articles described herein.

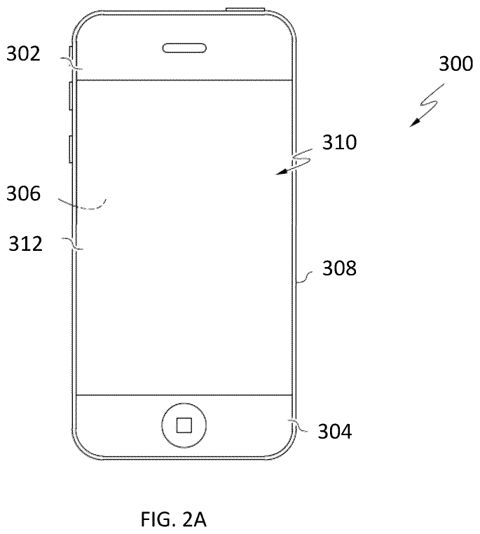

In embodiments, methods for texturing glass articles to form the dual-textured glass articles 100 described herein may include applying a mask to a portion of a first major surface of a glass article, contacting at least a portion of the first major surface of the glass article with a first etchant to impart a first texture to the first major surface of the glass article to form a textured glass article; removing at least a portion of the mask from the first major surface of the textured glass article; and further texturing the first major surface of the glass article to impart a second texture to the first major surface and thereby form a dual-textured glass article 100, where the second texture is different from the first texture. FIGS. 3A, 3B, and 3C schematically depict glass articles at various stages throughout the method for producing dual-textured glass articles 100 described herein.

Referring now to FIG. 3A, applying mask 400 to a portion of the first major surface 502 of the glass article 500 may comprise any suitable deposition method. In embodiments, a masking material may be sprayed or otherwise deposited onto the first major surface 502 of the glass article 500. For example, applying a mask 400 to the portion of the first major surface 502 of the glass article 500 may include inkjet printing, screen printing, or photo lithography.

In embodiments, the mask 400 may comprise any material that may be resistant to the first etchant. For example, inkjet inks that are curable with ultraviolet light may be suitable materials for the mask. Additionally, hydrocarbons with unsaturated double bonds, such as polyethylene, may be suitable masking materials. In embodiments, the mask 400 may be an ultraviolet curable inkjet ink and the mask 400 may be applied to the first major surface 502 of the glass article 500 by inkjet printing. For example, in embodiments, the ultraviolet curable inkjet ink may be UVink LH-100 Black from Mimaki®.

In embodiments, the mask 400 may be applied to the first major surface 502 of the glass article 500 in a random pattern. In embodiments, the mask 400 applied to the first major surface 502 of the glass article 500 may be discontinuous, while an unmasked area of the first major surface 502 of the glass article 500 may be continuous. In other words, each masked portion of the first major surface 502 of the glass article 500 may be substantially surrounded by an unmasked portion of the glass article 500, or an edge of the first major surface 502 of the glass article 500. In embodiments, the mask 400 may be dimensioned to form the first features 210 described hereinabove in regard to FIGS. 1A and 1B. For example, without limitation, the mask 400 may have any suitable shape, such as a substantially circular, elliptical, oval, or polygonal shape. Furthermore, the mask 400 may have any suitable size. For example, the mask 400 may have a size from 50 μm to 1000 μm, as described hereinabove with regard to the first features 210. It should be noted that the size and shape of the mask 400 applied to the first surface of the glass article may substantially correspond to the size and shape of the first features 210 of the dual-textured glass article 100. However, exact correspondence between the size and shape of the mask 400 and the first features 210 should not be expected due to the subsequent etching and polishing steps described herein.

In embodiments, contacting at least a portion of the first major surface 502 of the glass article 500 with a first etchant may impart a first texture to the first major surface 502 of the glass article 500 to form a textured glass article 600, depicted in FIG. 3B. The first etchant may be an aqueous solution comprising one or more of HF, nitric acid, and citric acid. In embodiments, the first etchant may comprise HF, a combination of HF and nitric acid, or citric acid. In embodiments, the first etchant may comprises citric acid and may be substantially free from HF. In embodiments, the first etchant may be an aqueous solution comprising from 1 wt. % to 10 wt. % of one or more of HF, nitric acid, and citric acid. For example, without limitation, the first etchant may comprise one or more of HF, nitric acid, and citric acid from 1 wt. % to 10 wt. %, from 3 wt. % to 10 wt. %, from 5 wt. % to 10 wt. %, from 7 wt. % to 10 wt. %, from 9 wt. % to 10 wt. %, from 1 wt. % to 9 wt. %, from 1 wt. % to 7 wt. %, from 1 wt. % to 5 wt. %, from 1 wt. % to 3 wt. %, or any sub-range formed from these endpoints.

Contacting at least a portion of the first major surface 502 of the glass article 500 with a first etchant may occur for a time sufficient to impart the first texture to the first major surface 502 of the glass article 500 to form a textured glass article 600. In embodiments where the first etchant comprises one or more of HF, nitric acid, and citric acid, the first major surface of the glass article may be contacted with the etchant for a time from 1 min. to 20 min. For example, without limitation, the first major surface of the glass article may be contacted with the etchant for a time from 1 min. to 20 min, from 5 min. to 20 min., from 10 min. to 20 min., from 15 min. to 20 min., from 1 min. to 15 min., from 1 min. to 10 min., from 1 min. to 5 min., or any sub-range formed from these endpoints.

In embodiments, the first etchant may be an aqueous solution comprising from 20 wt. % to 70 wt. % NaOH. For example, without limitation, the first etchant may be an aqueous solution comprising NaOH from 20 wt. % to 70 wt. %, from 30 wt. % to 70 wt. %, from 40 wt. % to 70 wt. %, from 50 wt. % to 70 wt. %, from 60 wt. % to 70 wt. %, from 20 wt. % to 60 wt. %, from 20 wt. % to 50 wt. %, from 20 wt. % to 40 wt. %, from 20 wt. % to 30 wt. %, or any sub-range formed from these endpoints. In such embodiments, the first etchant may be substantially free from HF.

In embodiments where the first etchant comprises NaOH, the first major surface 502 of the glass article 500 may be contacted with the etchant for a time from 10 min. to 60 min. For example, without limitation, the first major surface 502 of the glass article 500 may be contacted with the etchant for a time from 10 min. to 60 min., from 20 min. to 60 min., from 30 min. to 60 min., from 40 min to 60 min., from 50 min. to 60 min., from 10 min. to 50 min., from 10 min. to 40 min., from 10 min. to 30 min., from 10 min. to 20 min., or any sub-range formed from these endpoints. In embodiments where the first etchant comprises NaOH, the first major surface 502 of the glass article 500 may be contacted with the etchant at a temperature of from 95° C. to 170° C. For example, without limitation, the first major surface 502 of the glass article 500 may be contacted with the etchant at a temperature of from 95° C. to 170° C., from 100° C. to 170° C., from 110° C. to 170° C., from 120° C. to 170° C., from 130° C. to 170° C., from 140° C. to 170° C., from 150° C. to 170° C., from 160° C. to 170° C., from 95° C. to 160° C., from 95° C. to 150° C., from 95° C. to 140° C., from 95° C. to 130° C., from 95° C. to 120° C., from 95° C. to 110° C., from 95° C. to 100° C., or any sub-range formed from these endpoints.

Referring to FIG. 3B, methods for texturing glass articles described herein may comprise removing at least a portion of the mask 400 from the first features 610 of the textured glass article 600. The mask 400 may be entirely removed from the textured glass article 600. The mask 400 may be removed from the textured glass article 600 by any suitable means. For example, without limitation, the mask 400 may be removed by rinsing the textured glass article 600 with hot water. In embodiments, the mask 400 may be removed by the first etchant while the glass article 500 is being contacted with the first etchant. In such embodiments, it is contemplated that removal of the mask 400 may occur at or near the end of the contacting of the first etchant and the glass article 500.

Referring now to FIG. 3C, methods for texturing glass articles described herein may comprise further texturing the first major surface 602 of the textured glass article 600 to form a dual-textured glass article 100, as depicted in FIGS. 1A and 1B. In embodiments, texturing the first major surface 602 and the first features 610 of the textured glass article 600 may comprise abrading at least a portion of the first major surface 602 and the first features 610 of the textured glass article 600 by impinging abrasive particles against the first major surface 602 and the first features 610 and subsequently contacting at least a portion of the first major surface 602 and the first features 610 with a second etchant to form a dual-textured glass article 100.

In embodiments, the abrasion process may be a particulate blasting process, commonly referred to as media blasting or sand blasting, in which abrasive particles are propelled against the first major surface 602 and the first features 610 of the textured glass article 600 substrate by a pressurized fluid medium. The abrasion process may include one or more treatments of the surface. In embodiments, the abrasion process may be repeated one or more times to achieve the desired effect.

In embodiments, the abrasive particles may comprise sand, Al₂O₃, SiC, SiO₂, and combinations thereof. The abrasive particles may have a particle size selected to produce the desired abrading effect. In embodiments, the abrasive particles may have a particle size from 3 μm to 15 μm. For example, without limitation, the abrasive particles may have a particle size from 3 μm to 15 μm, from 5 μm to 15 μm, from 7 μm to 15 μm, from 9 μm to 15 μm, from 11 μm to 15 μm, from 13 μm to 15 μm, from 3 μm to 13 μm, from 3 μm to 11 μm, from 3 μm to 9 μm, from 3 μm to 7 μm, from 3 μm to 5 μm, or any sub-range formed from these endpoints.

The abrasion process may employ any appropriate pressurized fluid medium. For example, without limitation, the pressurized fluid medium may comprise air. The pressurized fluid medium may be at any suitable pressure. In embodiments, the abrasive particles may be propelled by a fluid medium at a pressure from 15 psi to 60 psi. For example, without limitation, abrasive particles may be propelled by a fluid medium at a pressure from 15 psi to 60 psi, from 20 psi to 60 psi, from 25 psi to 60 psi, from 30 psi to 60 psi, from 35 psi to 60 psi, from 40 psi to 60 psi, from 45 psi to 60 psi, from 50 psi to 60 psi, from 55 psi to 60 psi, from 15 psi to 55 psi, from 15 psi to 50 psi, from 15 psi to 45 psi, from 15 psi to 40 psi, from 15 psi to 35 psi, from 15 psi to 30 psi, from 15 psi to 25 psi, from 15 psi to 20 psi, or any sub-range formed from these endpoints.

After the abrasion process, the first major surface 602 and the first features 610 of the textured glass article 600 may be contacted with a second etchant. In embodiments, the second etchant may comprise a hydroxide, such as NaOH. In embodiments, the second etchant may be substantially free from HF. The second etchant may comprise an aqueous solution comprising NaOH at a concentration from 30 wt. % to 70 wt. %. For example, without limitation, the second etchant may comprise NaOH at a concentration from 30 wt. % to 70 wt. %, from 35 wt. % to 70 wt. %, from 40 wt. % to 70 wt. %, from 45 wt. % to 70 wt. %, from 50 wt. % to 70 wt. %, from 55 wt. % to 70 wt. %, from 60 wt. % to 70 wt. %, from 65 wt. % to 70 wt. %, from 30 wt. % to 65 wt. %, from 30 wt. % to 60 wt. %, from 30 wt. % to 55 wt. %, from 30 wt. % to 50 wt. %, from 30 wt. % to 45 wt. %, from 30 wt. % to 40 wt. %, from 30 wt. % to 35 wt. %, or any sub-range formed from these endpoints.

In embodiments, the first major surface 602 and the first features 610 of the textured glass article 600 may be contacted with the second etchant at a temperature of from 100° C. to 170° C. For example, without limitation, the first major surface 602 and the first features 610 of the textured glass article 600 may be contacted with the second etchant at a temperature of from 100° C. to 170° C., from 110° C. to 170° C., from 10° C. to 170° C., from 130° C. to 170° C., from 140° C. to 170° C., from 150° C. to 170° C., from 160° C. to 170° C., from 100° C. to 160° C., from 100° C. to 150° C., from 100° C. to 140° C., from 100° C. to 130° C., from 100° C. to 120° C., from 100° C. to 110° C., or any sub-range formed from these endpoints.

In embodiments, the first major surface 602 and the first features 610 of the textured glass article 600 may be contacted with the second etchant for a time from 30 min. to 120 min. For example, without limitation, the first major surface 602 and the first features 610 of the textured glass article 600 may be contacted with the second etchant for a time from 30 min. to 120 min., from 40 min. to 120 min., from 50 min. to 120 min., from 60 min. to 120 min., from 70 min. to 120 min., from 80 min. to 120 min., from 90 min. to 120 min., from 100 min. to 120 min., from 110 min. to 120 min., from 30 min. to 110 min., from 30 min. to 100 min., from 30 min. to 90 min., from 30 min. to 80 min., from 30 min. to 70 min., from 30 min. to 60 min., from 30 min. to 50 min., from 30 min. to 40 min., or any sub-range formed from these endpoints.

In some embodiments, texturing the first major surface 602 and the first features 610 of the textured glass article 600 does not comprise an abrasion or sand blasting process. In such embodiments, texturing the first major surface 602 and the first features 610 of the textured glass article 600 may comprise contacting the first major surface 602 and the first features 610 of the textured glass article 600 with a subsequent etchant and subsequently contacting at least a portion of the first major surface 602 and the first features 610 of the textured glass article 600 with a polish to form the dual-textured glass article 100, depicted in FIGS. 1A and 1B.

The subsequent etchant may be an aqueous solution comprising HF, NH₄F, and KCl or combinations thereof. In embodiments, the subsequent etchant may comprise from 2 wt. % to 6 wt. % HF. For example, without limitation, the subsequent etchant may comprise HF from 2 wt. % to 6 wt. %, from 3 wt. % to 6 wt. %, from 4 wt. % to 6 wt. %, from 5 wt. % to 6 wt. %, from 2 wt. % to 5 wt. %, from 2 wt. % to 4 wt. %, from 2 wt. % to 3 wt. %, or any sub-range formed from these endpoints. In embodiments, the subsequent etchant may comprise from 5 wt. % to 15 wt. % NH₄F. For example, without limitation, the subsequent etchant may comprise NH₄F from 5 wt. % to 15 wt. %, from 7 wt. % to 15 wt. %, from 9 wt. % to 15 wt. %, from 11 wt. % to 15 wt. %, from 13 wt. % to 15 wt. %, from 5 wt. % to 13 wt. %, from 5 wt. % to 11 wt. %, from 5 wt. % to 9 wt. %, from 5 wt. % to 7 wt. %, or any sub-range formed from these endpoints. In embodiments, the subsequent etchant may comprise KCl from 0 wt. % to 10 wt. %. For example, without limitation, the subsequent etchant may comprise KCl from 0 wt. % to 10 wt. %, from 1 wt. % to 10 wt. %, from 3 wt. % to 10 wt. %, from 5 wt. % to 10 wt. %, from 7 wt. % to 10 wt. %, from 9 wt. % to 10 wt. %, from 0 wt. % to 8 wt. %, from 0 wt. % to 6 wt. %, from 0 wt. % to 4 wt. %, from 0 wt. % to 2 wt. %, or any sub-range formed from these endpoints. In some embodiments, the subsequent etchant may be an aqueous solution comprising from 2 wt. % to 6 wt. % HF, from 5 wt. % to 15 wt. % NH₄F, and from 0 wt. % to 10 wt. % KCl.

In embodiments where the subsequent etchant comprises HF, NH₄F, and KCl or combinations thereof, the first major surface 602 and the first features 610 of the textured glass article 600 may be contacted with the subsequent etchant for a time from 1 min to 10 min. For example, without limitation, the first major surface 602 and the first features 610 of the textured glass article 600 may be contacted with the subsequent etchant for a time from 1 min. to 10 min. For example, without limitation, the first major surface 602 and the first features 610 of the textured glass article 600 may be contacted with the subsequent etchant for a time from 1 min. to 10 min., from 3 min. to 10 min., from 5 min. to 10 min., from 7 min. to 10 min., from 9 min. to 10 min., from 1 min. to 8 min., from 1 min. to 6 min., from 1 min. to 4 min., from 1 min. to 2 min., or any sub-range formed from these endpoints.

In embodiments where the subsequent etchant comprises HF, NH₄F, and KCl or combinations thereof, the polish may be an aqueous solution comprising from 1 vol. % to 3 vol. % HF. For example, the polish may be an aqueous solution comprising HF from 1 vol. % to 3 vol. %, from 2 vol. % to 3 vol. % or from 1 vol. % to 2 vol. %. The polish may be contacted with the first major surface 602 and the first features 610 of the textured glass article 600 for a time from 1 min. to 20 min. For example, without limitation, the polish may be contacted with the first major surface 602 and the first features 610 of the textured glass article 600 for a time from 1 min. to 20 min., from 3 min. to 20 min., from 5 min. to 20 min., from 7 min. to 20 min., from 9 min. to 20 min., from 11 min. to 20 min., from 13 min. to 20 min., from 15 min. to 20 min., from 17 min. to 20 min., from 19 min. to 20 min., from 1 min. to 18 min., from 1 min. to 16 min., from 1 min. to 14 min., from 1 min. to 12 min., from 1 min. to 10 min., from 1 min. to 8 min., from 1 min. to 6 min., from 1 min. to 4 min., from 1 min. to 2 min., or any sub-range formed from these endpoints.

In embodiments, the subsequent etchant may be substantially free from HF. In such embodiments the subsequent etchant may be an aqueous solution comprising from 2 wt. % to 8 wt. % HCl. For example, without limitation, the subsequent etchant may comprise HCl from 2 wt. % to 8 wt. %, from 3 wt. % to 8 wt. %, from 4 wt. % to 8 wt. %, from 5 wt. % to 8 wt. %, from 6 wt. % to 8 wt. %, from 7 wt. % to 8 wt. %, from 2 wt. % to 7 wt. %, from 2 wt. % to 6 wt. %, from 2 wt. % to 5 wt. %, from 2 wt. % to 4 wt. %, from 2 wt. % to 3 wt. %, or any sub-range formed from these endpoints.

In embodiments where the subsequent etchant comprises HCl, the first major surface 602 and the first features 610 of the textured glass article 600 may be contacted with the subsequent etchant for a time from 12 hr. to 48 hr. For example, the first major surface 602 and the first features 610 of the textured glass article 600 may be contacted with the subsequent etchant for a time from 12 hr. to 48 hr., from 18 hr. to 48 hr., from 24 hr. to 48 hr., from 30 hr. to 48 hr., from 36 hr. to 48 hr., from 42 hr. to 48 hr., from 12 hr. to 42 hr., from 12 hr. to 36 hr., from 12 hr. to 30 hr., from 12 hr. to 24 hr., from 12 hr. to 18 hr., or any sub-range formed from these endpoints. The first major surface 602 and the first features 610 of the textured glass article 600 may be contacted with the subsequent etchant at a temperature from 75° C. to 115° C. For example, without limitation, the first major surface 602 and the first features 610 of the textured glass article 600 may be contacted with the subsequent etchant at a temperature from 75° C. to 115° C., from 80° C. to 115° C., from 85° C. to 115° C., from 95° C. to 115° C., from 95° C. to 115° C., from 100° C. to 115° C., from 110° C. to 115° C., from 75° C. to 110° C., from 75° C. to 105° C., from 75° C. to 100° C., from 75° C. to 95° C., from 75° C. to 90° C., from 75° C. to 85° C., from 75° C. to 80° C., or any sub-range formed from these endpoints.

In embodiments where the subsequent etchant comprises HCl, the polish may be an aqueous solution comprising from 5 wt. % to 15 wt. % NaOH. For example, without limitation, the polish may be an aqueous solution comprising NaOH from 5 wt. % to 15 wt. %, from 7 wt. % to 15 wt. %, from 9 wt. % to 15 wt. %, from 11 wt. % to 15 wt. %, from 13 wt. % to 15 wt. %, from 5 wt. % to 13 wt. %, from 5 wt. % to 11 wt. %, from 5 wt. % to 9 wt. %, from 5 wt. % to 7 wt. %, or any sub-range formed from these endpoints. The polish may be contacted with the first major surface 602 and the first features 610 of the textured glass article 600 for a time from 15 min. to 30 min. For example, without limitation, the polish may be contacted with the first major surface 602 and the first features 610 of the textured glass article 600 for a time from 15 min. to 30 min., from 17 min. to 30 min., from 19 min. to 30 min., from 21 min. to 30 min., from 23 min. to 30 min., from 25 min. to 30 min., from 27 min. to 30 min., from 29 min. to 30 min., from 15 min. to 28 min., from 15 min. to 26 min., from 15 min. to 24 min., from 15 min. to 22 min., from 15 min. to 20 min., from 15 min. to 18 min., from 15 min. to 16 min., or any sub-range formed from these endpoints. The polish may be contacted with the first major surface 602 and the first features 610 of the textured glass article 600 at a temperature from 75° C. to 115° C. For example, without limitation, the first major surface 602 and the first features 610 of the textured glass article 600 may be contacted with the polish at a temperature from 75° C. to 115° C., from 80° C. to 115° C., from 85° C. to 115° C., from 95° C. to 115° C., from 95° C. to 115° C., from 100° C. to 115° C., from 110° C. to 115° C., from 75° C. to 110° C., from 75° C. to 105° C., from 75° C. to 100° C., from 75° C. to 95° C., from 75° C. to 90° C., from 75° C. to 85° C., from 75° C. to 80° C., or any sub-range formed from these endpoints.

In embodiments, texturing the first major surface 602 and the first features 610 of the textured glass article 600 to form a dual-textured glass article 100 does not include texturing the second major surface 604 of the textured glass article 600. For example, the second major surface 604 of the textured glass article 600 may not be contacted with the abrasive particles, the second etchant, the subsequent etchant, or the polish described herein. In embodiments, the second major surface 604 of the textured glass article 600 may be masked or otherwise covered such that the second major surface 604 is not textured during the process steps used to texture the first major surface 602 of the textured glass article. Without intending to be bound by theory, it may be advantageous for the second major surface 104 of the dual-textured glass article 100 to remain untextured, as texturing the second major surface 104 may have little advantage when using the dual-textured glass article 100 as a cover for a display.

### EXAMPLES

The embodiments described herein will be further clarified by the following examples.

### Example 1— Masking and Etching Glass Articles to Form Textured Glass Articles

A series of circular dots were printed onto the first major surfaces of a series of glass articles to mask at least a portion of the first major surfaces of the glass articles. The glass articles were Corning Gorilla Glass 2320 having the following composition: 67.56 mol. % SiO₂, 12.67 mol. % Al₂O₃, 3.68 mol. % B₂O₃, 2.33 mol. % MgO, 13.67 mol. % NaO₂. The series of dots were printed onto the glass articles using inkjet printing. The ink was UVink LH-100 Black from Mimaki®. The size (diameter) of the dots and the distance between the dots for each sample is included in Table 1. The pattern for the dots was generated so that the dots were placed at the desired dot distance with the dot distance measured from center to center.

After the mask was printed onto each glass article, the glass articles were each etched. In the etching process, the glass articles were contacted with an aqueous solution comprising from 1 wt. % to 10 wt. % HF. The etching time was from 1 min. to 20 min. The composition of the aqueous solution and the etching time were adjusted to achieve the desired etch depths. The depth of the etch for each glass article is also included in Table 1. Some samples were etched to multiple depths using multiple etch steps, which is indicated by multiple etch depths listed in table 1. After the etching step, the mask was removed from each glass article. Etching the glass articles of Example 1 formed a first texture on the first major surface of the glass articles.

TABLE 1
Mask and Etching Design.

| | Dot Size | Dot Distance | Etch Depth |
|---|---|---|---|
| Group | (μm) | (μm) | (nm) |
| 1 | 50 | 50 | 40, 100, 400 |
| 2 | 100 | 50 | 40, 100, 400 |
| 3 | 100 | 100 | 40, 100, 400 |
| 4 | 200 | 200 | 40, 100, 400 |
| 5 | 200 | 700 | 400, 1000, 2000, 5000 |
| 6 | 700 | 700 | 400, 1000, 2000, 5000 |
| 7 | 700 | 1000 | 400, 1000, 2000, 5000 |
| 8 | 1000 | 1500 | 400, 1000, 2000, 5000 |
| 9 | 50 | 100 | 5000 |
| 10 | 50 | 300 | 5000 |
| 11 | 100 | 100 | 5000 |
| 12 | 100 | 300 | 5000 |
| 13 | 200 | 100 | 5000 |
| 14 | 200 | 300 | 5000 |

### Example 2— Sandblasting and Etching Glass Articles to Form Dual-Textured Glass Articles

The textured glass articles of groups 9-14 of Example 1 were sandblasted on a single side. The sandblasting media was Al₂O₃ and SiC having a particle size from 3 μm to 15 μm. The pressure of the fluidizing medium was from 15 psi to 60 psi. Each sample was then etched in an aqueous solution comprising 50 wt. % NaOH for a duration of 1 hour at a temperature of 120° C. The sandblasting and subsequent etching imparted a second texture to the textured glass articles of Example 1 to form dual-textured glass articles. The optical properties of the dual-textured glass articles of Example 2 are included in Table 2. The optical properties of the dual-textured glass articles may be tuned by adjusting the sandblasting and etching conditions.

TABLE 2
Dual Textured Glass Article Properties

| | Dot Size | Dot Distance | Dot Height | Roughness | Haze | |
|---|---|---|---|---|---|---|
| Group | (μm) | (μm) | (μm) | (Rₐ) (μm) | (%)(BYK) | Gloss 60° |
| 9 | 50 | 100 | 3.2779 | 0.6739 | 22.2 | 32.4 |
| 10 | 50 | 300 | 2.6634 | 0.3961 | 18 | 36.28 |
| 11 | 100 | 100 | 2.2942 | 0.7168 | 22 | 30.87 |
| 12 | 100 | 300 | 2.4657 | 0.6249 | 26.3 | 27.59 |
| 13 | 200 | 100 | 4.7754 | 1.542 | 32.2 | 24.77 |
| 14 | 200 | 300 | 4.747 | 1.4178 | 28.6 | 26.33 |

| | | | Diffusion | S′*100 (Sparkle %) | S′*100 (Sparkle %) |
|---|---|---|---|---|---|
| Group | Rspec | DOI | (SMS) | 220 ppi 0° angle | 220 ppi 45° angle |
| 9 | 4.04 | 45.84 | 79.394 | 12.11 | 10.69 |
| 10 | 7.4 | 74.05 | 37.295 | 7.38 | 6.94 |
| 11 | 2.96 | 21.99 | 62.742 | 12.48 | 12.09 |
| 12 | 5.59 | 74.65 | 46.114 | 5.98 | 6.19 |
| 13 | 3.51 | 58.92 | 76.659 | 7.68 | 9.95 |
| 14 | 4.89 | 71.12 | 58.867 | 8.02 | 7.8 |

The properties in Table 2 include the dot size, the distance between the dots, and the height of the dots, as described previously. Additionally, Table 2 includes the surface roughness (Rₐ), diffusion, Haze, distinctness-of-image, Gloss 60°, and Sparkle as described previously. Table 2 also includes an Rspec value. As described herein, the Rspec value is a measurement of specular reflection. Rspec may be measured using a commercially available Rhopoint Gloss Meter.

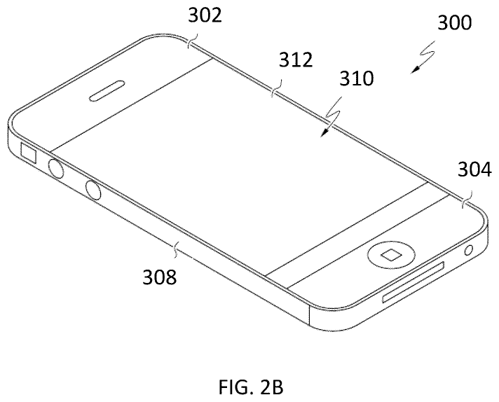

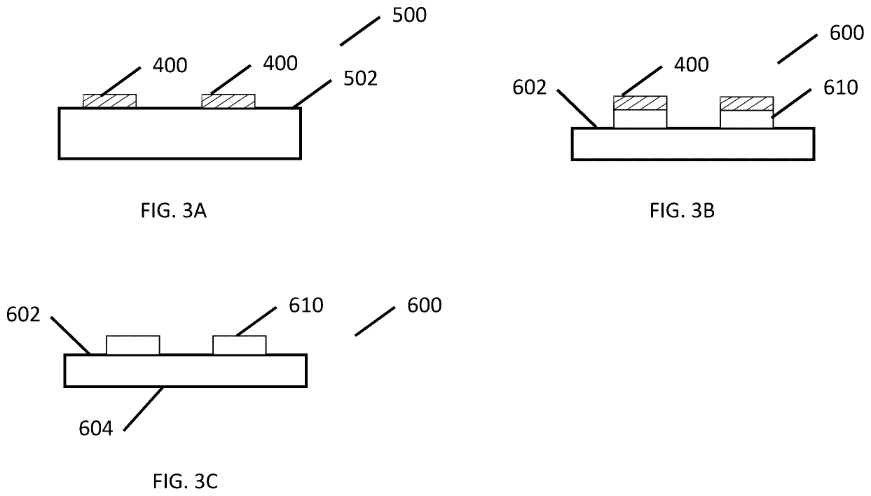

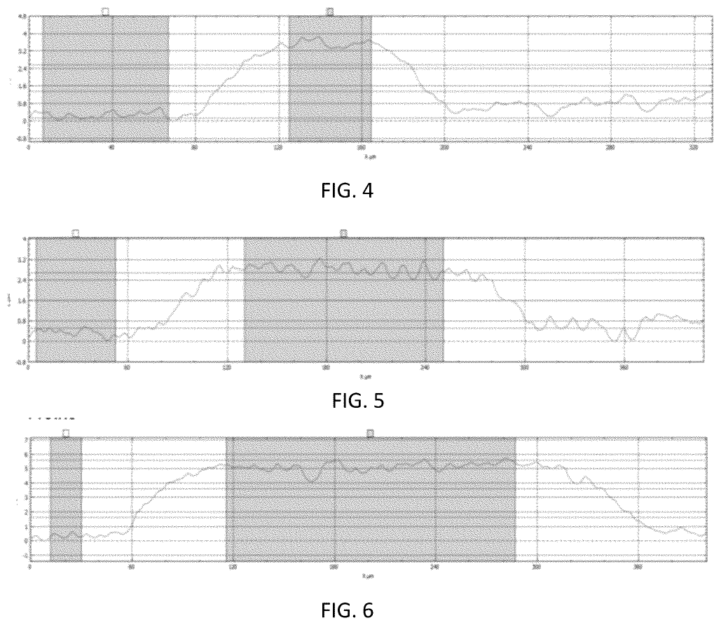

The dual-textured glass articles of groups 9, 12, and 14 of Example 2 were characterized by laser confocal microscopy. The profile of the surface of the dual-textured glass article of groups 9, 12, and 14 are displayed in FIGS. 4, 5, and 6 respectively. The height of the first texture imparted to the glass articles in Example 1, is given in Table 2. The depth of the second textures imparted to the glass articles by the sandblasting and etching described in Example 2, were from 5 μm to 10 μm. The depth of the second texture may be tuned by adjusting the sandblasting and etching conditions.

The present disclosure is directed to various embodiments of dual-textured glass articles and methods of making dual-textured glass articles. In embodiments, dual-textured glass articles comprise a glass substrate comprising a first major surface and a second major surface, the first major surface opposite the second major surface, wherein at least a portion of the first major surface comprises a dual-texture, the dual-texture comprising a plurality of first features and a plurality of second features, wherein the plurality of first features comprise protrusions from the first major surface and the plurality of second features comprise indentations in the first major surface and indentations in the plurality of first features. The dual-textured glass articles may be suitable for use as part of the display of an electronic device and may provide a paper-like tactile experience when interacting with the dual-textured surface of the glass article with a stylus.

It will be apparent to those skilled in the art that various modifications and variations can be made to the embodiments described herein without departing from the spirit and scope of the claimed subject matter. Thus, it is intended that the specification cover the modifications and variations of the various embodiments described herein provided such modification and variations come within the scope of the appended claims and their equivalents.

1. A dual-textured glass article comprising:
a glass substrate comprising a first major surface and a second major surface, the first major surface opposite the second major surface;
wherein at least a portion of the first major surface comprises a dual-texture, the dual-texture comprising a plurality of first features and a plurality of second features, wherein the plurality of first features comprise protrusions from the first major surface and the plurality of second features comprise indentations in the first major surface and indentations in the plurality of first features.

2. The dual-textured glass article of claim 1, wherein the plurality of first features are randomly arranged on the first major surface.

3. The dual-textured glass article of claim 1, wherein the dual-textured glass article comprises from 55 mol. % to 70 mol. % SiO₂, from 10 mol. % to 20 mol. % Al₂O₃, from 0 mol. % to 5 mol. % P₂O₅, from 0 mol. % to 5 mol. % B₂O₃, from 0 mol. % to 5 mol. % MgO, from 0 mol. % to 2.5 mol. % ZnO, from 0 mol. % to 10 mol. % Li₂O, from 5 mol. % to 15 mol. % Na₂O, from 0 mol. % to 1 mol. % K₂O, and from 0 mol. % to 1 mol. % TiO₂.

4. The dual-textured glass article of claim 1, wherein the plurality of first features have sizes from 50 μm to 1000 μm, wherein the size of the plurality of first features is a diameter of a smallest circle enclosing individual ones of the plurality of first features at the first major surface.

5. The dual-textured glass article of claim 1, wherein the plurality of first features have heights from 0.1 μm to 10 μm.

6. The dual-textured glass article of claim 1, wherein a distance between first features is from 50 μm to 1500 μm.

7. The dual-textured glass article of claim 1, wherein the plurality of second features have sizes from 0.5 μm to 20 μm, wherein the size of the plurality of second features is a diameter of a smallest circle enclosing individual ones of the plurality of second features at the first major surface.

8. The dual-textured glass article of claim 1, wherein the plurality of second features have depths from 0.1 μm to 1.5 μm.

9. The dual-textured glass article of claim 1, wherein the portion of the first major surface comprising the dual-texture has a haze of from 1% to 40%.

10. The dual-textured glass article of claim 1, wherein the portion of the first major surface comprising the dual-texture has a surface roughness Rₐ of from 0.1 μm to 1.5 μm.

11. The dual-textured glass article of claim 1, wherein the portion of the first major surface comprising the dual-texture has sparkle of less than or equal to 7%.

12. The dual-textured glass article of claim 1, wherein the portion of the first major surface comprising the dual-texture has a diffusion of greater than or equal to 20%.

13. A consumer electronic product comprising:
a housing having a front surface, a back surface, and side surfaces;
electrical components provided at least partially within the housing, the electrical components including at least a controller, a memory and a display, the display being provided at or adjacent the front surface of the housing; and
a cover substrate disposed over the display, wherein the cover substrate comprises the dual-textured glass article of claim 1.

14. A method of texturing a glass article, the method comprising:
applying a mask to a portion of a first major surface of the glass article;
contacting at least a portion of the first major surface of the glass article with a first etchant to impart a first texture to the first major surface of the glass article to form a textured glass article;
removing at least a portion of the mask from the first major surface of the textured glass article; and
texturing the first major surface of the textured glass article to impart a second texture to the first major surface and thereby form a dual-textured glass article, wherein the second texture is different from the first texture.

15. The method of claim 14, wherein applying a mask to at least a portion of the first major surface of the glass article comprises inkjet printing, screen printing, or photo lithography.

16. The method of claim 14, wherein the first etchant is an aqueous solution comprising from 1 wt. % to 10 wt. % of one or more of HF, nitric acid, and citric acid.

17. The method of claim 16, wherein at least a portion of the first major surface of the glass article is contacted with the first etchant for a time from 1 min. to 20 min.

18. The method of claim 14, wherein the first etchant is an aqueous solution comprising from 20 wt. % to 70 wt. % NaOH.

19. The method of claim 18, wherein at least a portion of the first major surface of the glass article is contacted with the first etchant for a time from 10 min. to 60 min. and at a temperature of from 95° C. to 170° C.

20. The method of claim 14, wherein texturing the first major surface of the textured glass article comprises abrading at least a portion of the first major surface of the textured glass article by impinging abrasive particles against the first major surface and contacting at least a portion of the first major surface of the textured glass article with a second etchant.

21. The method of claim 20, wherein the abrasive particles comprise sand, Al₂O₃, SiC, SiO₂ and combinations thereof.

22. The method of claim 20, wherein the abrasive particles have a particle size from 3 μm to 15 μm.

23. The method of claim 20, wherein the second etchant is an aqueous solution comprising from 30 wt. % to 70 wt. % NaOH.

24. The method of claim 20, wherein contacting the at least a portion of the first major surface of the textured glass article with the second etchant occurs for a time from 30 min. to 120 min. and at a temperature from 100° C. to 170° C.

25. The method of claim 14, wherein texturing the first major surface of the textured glass article comprises contacting at least a portion of the first major surface of the textured glass article with a subsequent etchant and contacting at least a portion of the first major surface of the textured glass article with a polish.

26. The method of claim 25, wherein the subsequent etchant is an aqueous solution comprising from 2 wt. % to 6 wt. % HF, from 5 wt. % to 15 wt. % NH4F, and from 0 wt. % to 10 wt. % KCl, and the polish is an aqueous solution comprising from 1 vol. % to 3 vol. % HF.

27. The method of claim 26, wherein the contacting at least a portion of the first major surface of the textured glass article with a subsequent etchant occurs for a time of from 1 min. to 10 min., and wherein contacting at least a portion of the first major surface of the textured glass article with a polish occurs for a time from 1 min. to 20 min.

28. The method of claim 25, wherein the subsequent etchant is an aqueous solution comprising from 2 wt. % to 8 wt. % HCl, and the polish comprises from 5 wt. % to 15 wt. % NaOH.

29. The method of claim 28, wherein the contacting at least a portion of the first major surface of the textured glass article with a subsequent etchant occurs for a time of from 12 hr. to 48 hr., and wherein contacting at least a portion of the first major surface of the textured glass article with a polish occurs for a time from 15 min. to 30 min.
